(19) United States
(12) Patent Application Publication
(10) Pub. No.: US 2016/0093567 A1
(43) Pub. Date: Mar. 31, 2016

(54) SYSTEM, APPARATUS, AND METHOD OF INTERCONNECTION IN A SUBSTRATE

(71) Applicant: QUALCOMM Incorporated, San Diego, CA (US)

(72) Inventors: Chin-Kwan KIM, San Diego, CA (US); Rajneesh KUMAR, San Diego, CA (US); Layal ROUHANA, San Diego, CA (US); Joan Rey V. BUOT, San Diego, CA (US); Omar James BCHIR, San Marcos, CA (US)

(21) Appl. No.: 14/498,397

(22) Filed: Sep. 26, 2014

(51) Int. Cl. H01L 23/522; H01L 21/768

(52) U.S. Cl. CPC H01L 23/5226; H01L 23/5223; H01L 21/76898; H01L 21/76834

(57) ABSTRACT

A semiconductor substrate according to some examples of the disclosure may include a substrate with a cavity in a top surface of the substrate, a plurality of cavity interconnections embedded below a bottom surface of the cavity and extending to a bottom surface of the substrate, and a plurality of side interconnections to either side of the cavity extending from the top surface of the substrate to the bottom surface of the substrate. Each of the plurality of side interconnections may include an electrically conductive stop etch layer in the same horizontal plane as the bottom of the cavity.

### FIELD OF DISCLOSURE

This disclosure relates generally to interconnections in a semiconductor substrate, and more specifically, but not exclusively, to interconnections in a cavity of a semiconductor substrate.

### BACKGROUND

Conventionally, semiconductor packages include a semiconductor die and a substrate with routing or conductive paths for the die extending through the substrate. Having a cavity in the substrate is beneficial in that it reduces the vertical profile or height of the package when the die is located in the cavity. However, locating a die in the cavity provides challenges for creating the routing or conductive paths because the substrate surface is no longer even and easy to uniformly pattern and layer for creating the conductive paths. Therefore, conductive paths are generally added by additional manufacturing steps on the surface of the bottom of the cavity only. This adds steps to the manufacturing process and limits the area where conductive paths are created—namely the cavity region.

Accordingly, there are industry needs for methods that improve upon conventional methods including the improved methods and apparatus provided hereby.

The inventive features that are characteristic of the teachings, together with further features and advantages, are better understood from the detailed description and the accompanying figures. Each of the figures is provided for the purpose of illustration and description only, and does not limit the present teachings.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

Some examples of the disclosure are directed to systems, apparatus, and methods for a semiconductor substrate include a substrate having a top side, a bottom side opposite the top side, a cavity in the top side of the substrate, a first side portion horizontally adjacent the cavity, and a second side portion horizontally adjacent the cavity opposite from the first side portion; a plurality of cavity interconnections located in a bottom surface of the cavity, the plurality of cavity interconnections providing a conductive path between the cavity and the bottom side; a plurality of first side interconnections located in the first side portion and extending from the top side of the substrate to the bottom side of the substrate; and a plurality of second side interconnections located in the second side portion and extending from the top side of the substrate to the bottom side of the substrate.

In some examples of the disclosure, the system, apparatus, and method includes applying a seed layer to a carrier; applying a first removable layer on a surface of the seed layer; patterning the first removable layer to create a cavity region, a plurality of first side interconnect regions horizontally adjacent to the cavity region, and a plurality of second side interconnect regions horizontally adjacent to the cavity region on an opposite side from the plurality of second side interconnect regions; applying an first electrically conductive material in the cavity region, the plurality of first side interconnect regions, and the plurality of second side interconnect regions; applying an electrically conductive etch stop layer on the first electrically conductive material; applying a second removable layer on the electrically conductive etch stop layer and the patterned first removable layer; patterning the second removable layer to form a plurality of cavity interconnect regions and to continue to form the plurality of first side interconnect regions and the plurality of second side interconnect regions; applying a second electrically conductive material in the plurality of cavity interconnect regions, the plurality of first side interconnect regions, and the plurality of second side interconnect regions; removing the first removable layer and the second removable layer; applying a dielectric layer on a surface of the second electrically conductive material; removing the seed layer and the carrier to expose the cavity region; and removing the first electrically conductive material from the cavity region.

Other features and advantages associated with the apparatus and methods disclosed herein will be apparent to those skilled in the art based on the accompanying drawings and detailed description.

### BRIEF DESCRIPTION OF THE DRAWINGS

The accompanying drawings are presented to describe examples of the present teachings, and are not limiting. The accompanying drawings are presented to aid in the description of examples of the disclosure and are provided solely for illustration of the examples and not limitation thereof.

FIG. 1 depicts a semiconductor substrate with a cavity having embedded interconnections in accordance with some examples of the disclosure.

FIG. 2 depicts a semiconductor package with a cavity having embedded interconnections and a semiconductor die in accordance with some examples of the disclosure.

FIG. 3 depicts a semiconductor package with a cavity having embedded interconnections, a semiconductor die, and a capacitor in accordance with some examples of the disclosure.

FIGS. 4A-R depict a partial process flow for forming a semiconductor package with a cavity having embedded interconnections in accordance with some examples of the disclosure.

FIGS. 5A-Q depict a partial process flow for forming a semiconductor package with a cavity having embedded interconnections and separately formed side interconnections in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Methods, apparatus and systems for semiconductor substrate interconnections are provided. The exemplary methods, apparatus, and systems disclosed herein advantageously address the industry needs, as well as other previously unidentified needs, and mitigate shortcomings of the conventional methods, apparatus, and systems. For example, a semiconductor substrate according to some examples of the disclosure may include a substrate with a cavity in a top surface of the substrate, a plurality of cavity interconnections embedded below a bottom surface of the cavity and extending to a bottom surface of the substrate, and a plurality of side interconnections to either side of the cavity extending from the top surface of the substrate to the bottom surface of the substrate. Each of the plurality of side interconnections may include an electrically conductive stop etch layer in the same horizontal plane as the bottom of the cavity.

Various aspects are disclosed in the following description and related drawings to show specific examples relating to the disclosure. Alternate examples will be apparent to those skilled in the pertinent art upon reading this disclosure, and may be constructed and practiced without departing from the scope or spirit of the disclosure. Additionally, well-known elements will not be described in detail or may be omitted so as to not obscure the relevant details of the aspects and examples disclosed herein.

The word “exemplary” is used herein to mean “serving as an example, instance, or illustration.” Any details described herein as “exemplary” is not necessarily to be construed as preferred or advantageous over other examples. Likewise, the term “examples” does not require that all examples include the discussed feature, advantage or mode of operation. Use of the terms “in one example,” “an example,” “in one feature,” and/or “a feature” in this specification does not necessarily refer to the same feature and/or example. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples only and is not intended to be limiting of examples of the disclosure. As used herein, the singular forms “a,” “an,” and “the” are intended to include the plural forms as well, unless the context clearly indicates otherwise. It will be further understood that the terms “comprises”, “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element. Coupling and/or connection between the elements can be physical, logical, or a combination thereof. As employed herein, elements can be “connected” or “coupled” together, for example, by using one or more wires, cables, and/or printed electrical connections, as well as by using electromagnetic energy. The electromagnetic energy can have wavelengths in the radio frequency region, the microwave region and/or the optical (both visible and invisible) region. These are several non-limiting and non-exhaustive examples.

Any reference herein to an element using a designation such as “first,” “second,” and so forth does not limit the quantity and/or order of those elements. Rather, these designations are used as a convenient method of distinguishing between two or more elements and/or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” used in the description or the claims can be interpreted as “A or B or C or any combination of these elements.”

The examples described below may be incorporated into a mobile device. The term “mobile device” can describe, and is not limited to, a mobile phone, a mobile communication device, a pager, a personal digital assistant, a personal information manager, a mobile hand-held computer, a laptop computer, a wireless device, a wireless modem, and/or other types of portable electronic devices typically carried by a person and/or having communication capabilities (e.g., wireless, cellular, infrared, short-range radio, etc.). Further, the terms “user equipment” (UE), “mobile terminal,” “mobile device,” and “wireless device,” can be interchangeable.

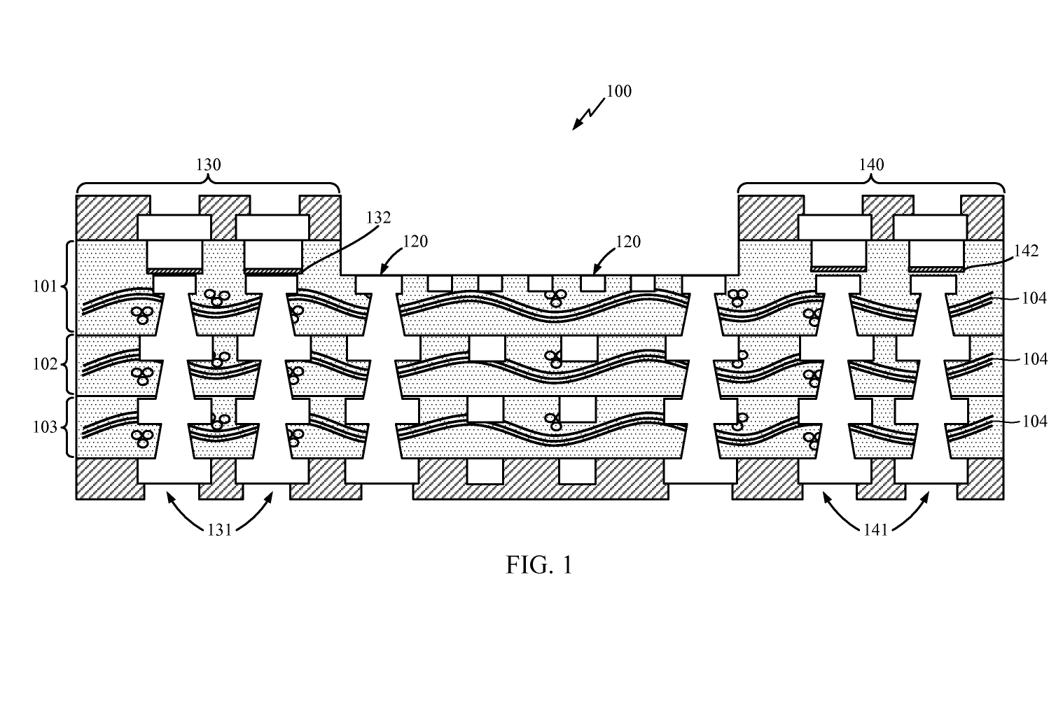

FIG. 1 depicts a semiconductor substrate with a cavity having embedded interconnections in accordance with some examples of the disclosure. As shown in FIG. 1, a semiconductor substrate 100 may include a first substrate layer 101, a second substrate layer 102, and a third substrate layer 103. While three substrate layers are shown, it should be understood that more or less substrate layers may be included. The first substrate layer 101 forms a top or first side of substrate 100 and is vertically above the second substrate layer 102. The second substrate layer 102 forms a middle of substrate 100 and is vertically above the third substrate layer 103. The third substrate layer 103 forms a bottom or second side of substrate 100. Each substrate layer 101-103 may include an embedded glass fiber or cloth 104 (pre-preg) extending horizontally throughout the layer. The embedded glass fiber 104 may be vertically centered within the respective layer or may be offset as shown in the first substrate layer 101. The offset of the glass fiber 104 in the first substrate layer 101 allows for the formation of cavity 110 without damaging the glass fiber 104.

The semiconductor substrate 100 may include a cavity 110, a plurality of cavity interconnections 120 in the cavity 110, a third side region 130, and a fourth side region 140. The cavity 110 is horizontally centered in the first substrate layer 101 on a top or first side of substrate 100. While the cavity 110 is shown horizontally centered in the substrate 100, it should be understood that the cavity 110 may be offset from the center of the substrate 100. While the cavity 110 is shown extending from the top or first side of substrate 100 into the first substrate layer 101, is should be understood that the cavity 110 can extend beyond the first substrate layer including extending into the third substrate layer 103.

The plurality of cavity interconnections 120 may be embedded in a bottom surface of the cavity 110 such that each of the plurality of cavity interconnections 120 is recessed or below a horizontal plane of the bottom surface of the cavity 110. The plurality of cavity interconnections 120 may be vertically below the bottom surface of the cavity 110 at various depths but preferably between 1 and 4 microns deep. The plurality of cavity interconnections 120 may provide a conductive path within the substrate 100 between each of the plurality of cavity interconnections 120 as well as between the plurality of cavity interconnections 120 and both the third side region 130 and the fourth side region 140.

The third side region 130 is horizontally adjacent to the cavity 110 on a left side of the cavity 110 and the fourth side region 140 is horizontally adjacent to the cavity 110 on a right side of the cavity 110 opposite the third side region 130. The third side region 130 and the fourth side region 140 extend from the top or first side of substrate 100 to the bottom or second side of substrate 100. The third side region may include a plurality of third side interconnections 131 extending from the top or first side of the substrate 100 to the bottom or second side of the substrate 100. Each of the plurality of third side interconnections 131 may include an electrically conductive stop etch layer 132 located within the first substrate layer 101 in the same horizontal plane as the bottom of the cavity 110 (horizontally above a surface of the plurality of cavity interconnections 120). The plurality of third side interconnections 131 may provide a conductive path from the top or first side of the substrate 100 to the bottom or second side of the substrate 100 as well as to the plurality of cavity interconnections 120 and, thorough the plurality of cavity interconnections 120, to a plurality of fourth side interconnections 141.

The fourth side region 140 may include a plurality of fourth side interconnections 141 extending from the top or first side of the substrate 100 to the bottom or second side of the substrate 100. Each of the plurality of fourth side interconnections 111 may include an electrically conductive stop etch layer 142 located within the first substrate layer 101 in the same horizontal plane as the bottom of the cavity 110 (horizontally above a surface of the plurality of cavity interconnections 120). The plurality of fourth side interconnections 141 may provide a conductive path from the top or first side of the substrate 100 to the bottom or second side of the substrate 100 as well as to the plurality of cavity interconnections 120 and, thorough the plurality of cavity interconnections 120, to the plurality of third side interconnections 131.

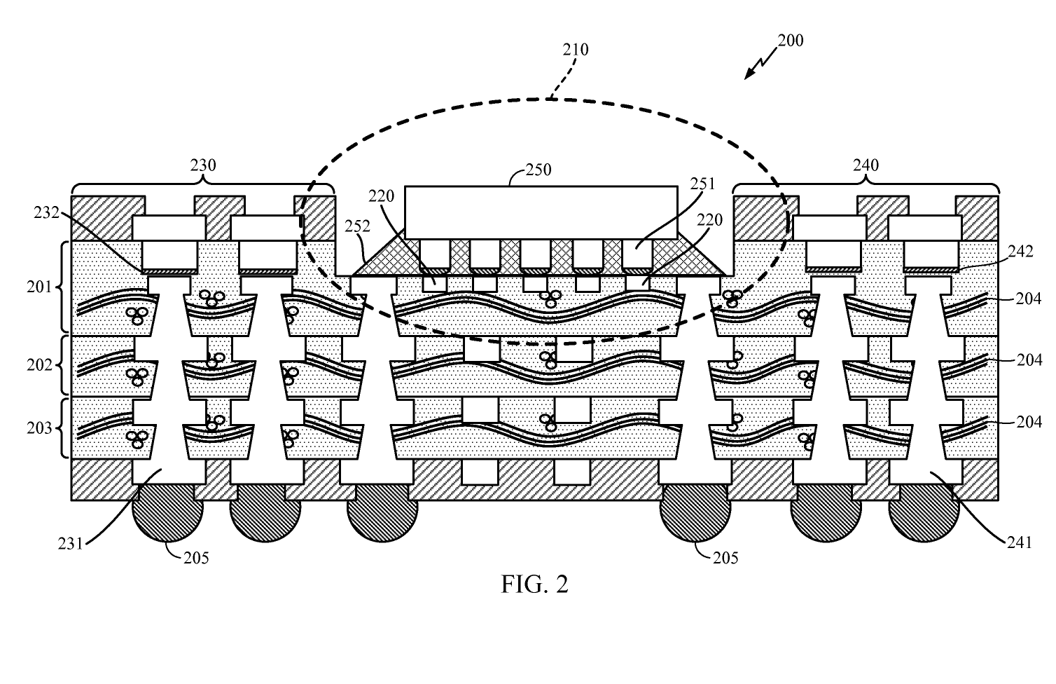

FIG. 2 depicts a semiconductor package with a cavity having embedded interconnections and a semiconductor die in accordance with some examples of the disclosure. As shown in FIG. 2, a semiconductor substrate 200 may include a first substrate layer 201, a second substrate layer 202, and a third substrate layer 203. While three substrate layers are shown, it should be understood that more or less substrate layers may be included. The first substrate layer 201 forms a top or first side of substrate 200 and is vertically above the second substrate layer 202. The second substrate layer 202 forms a middle of substrate 200 and is vertically above the third substrate layer 203. The third substrate layer 203 forms a bottom or second side of substrate 200. Each substrate layer 201-203 may include an embedded glass fiber or cloth 204 (pre-preg) extending horizontally throughout the layer. The embedded glass fiber 204 may be vertically centered within the respective layer or may be offset as shown in the first substrate layer 201. The offset of the glass fiber 204 in the first substrate layer 201 allows for the formation of cavity 210 without damaging the glass fiber 204.

The semiconductor substrate 200 may include a cavity 210, a plurality of cavity interconnections 220 in the cavity 210, a third side region 230, a fourth side region 240, and a semiconductor die 250. The cavity 210 is horizontally centered in the first substrate layer 201 on a top or first side of substrate 200. While the cavity 210 is shown horizontally centered in the substrate 200, it should be understood that the cavity 210 may be offset from the center of the substrate 200. While the cavity 210 is shown extending from the top or first side of substrate 200 into the first substrate layer 201, is should be understood that the cavity 210 can extend beyond the first substrate layer including extending into the third substrate layer 203.

The plurality of cavity interconnections 220 may be embedded in a bottom surface of the cavity 210 such that each of the plurality of cavity interconnections 220 is recessed or below a horizontal plane of the bottom surface of the cavity 210. The plurality of cavity interconnections 220 may be vertically below the bottom surface of the cavity 210 at various depths but preferably between 1 and 4 microns deep. The plurality of cavity interconnections 220 may provide a conductive path within the substrate 200 between each of the plurality of cavity interconnections 220 as well as between the plurality of cavity interconnections 220 and both the third side region 230 and the fourth side region 240.

The third side region 230 is horizontally adjacent to the cavity 210 on a left side of the cavity 210 and the fourth side region 240 is horizontally adjacent to the cavity 210 on a right side of the cavity 210 opposite the third side region 230. The third side region 230 and the fourth side region 240 extend from the top or first side of substrate 200 to the bottom or second side of substrate 200. The third side region may include a plurality of third side interconnections 231 extending from the top or first side of the substrate 200 to the bottom or second side of the substrate 200. Each of the plurality of third side interconnections 231 may include an electrically conductive stop etch layer 232 located within the first substrate layer 201 in the same horizontal plane as the bottom of the cavity 210 (horizontally above a surface of the plurality of cavity interconnections 220). The plurality of third side interconnections 231 may provide a conductive path from the top or first side of the substrate 200 to the bottom or second side of the substrate 200 as well as to the plurality of cavity interconnections 220 and, thorough the plurality of cavity interconnections 220, to a plurality of fourth side interconnections 241.

The fourth side region 240 may include a plurality of fourth side interconnections 241 extending from the top or first side of the substrate 200 to the bottom or second side of the substrate 200. Each of the plurality of fourth side interconnections 211 may include an electrically conductive stop etch layer 242 located within the first substrate layer 201 in the same horizontal plane as the bottom of the cavity 210 (horizontally above a surface of the plurality of cavity interconnections 220). The plurality of fourth side interconnections 241 may provide a conductive path from the top or first side of the substrate 200 to the bottom or second side of the substrate 200 as well as to the plurality of cavity interconnections 220 and, thorough the plurality of cavity interconnections 220, to the plurality of third side interconnections 231.

The semiconductor die 250 may be a number of different devices, such as a logic die or a memory die. The semiconductor die 250 may be centered within cavity 210 and include die connections 251 and underfill material 252. The die connections 251 couple the die 250 to the plurality of cavity interconnections 220. The substrate 200 may also include solder balls or connection points 205 that provide an external connection for the interconnections 220, 231, and 241 to other devices or components not shown, such as a printed circuit board.

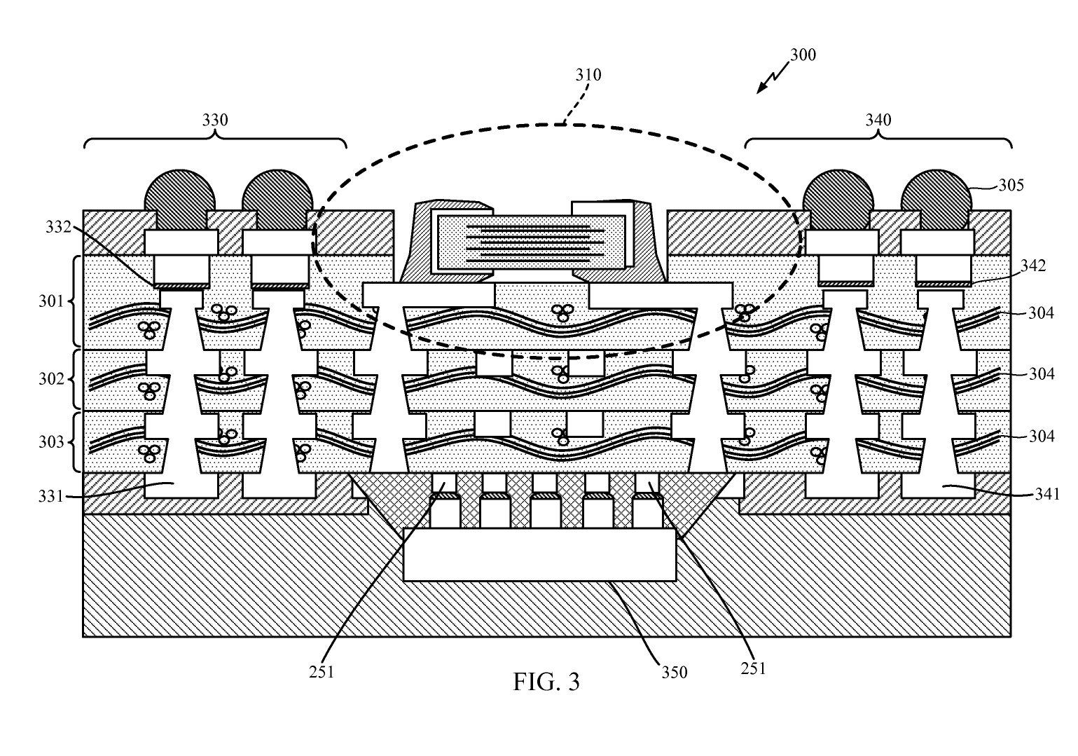

FIG. 3 depicts a semiconductor package with a cavity having embedded interconnections, a semiconductor die, and a capacitor in accordance with some examples of the disclosure. As shown in FIG. 3, a semiconductor substrate 300 may include a first substrate layer 301, a second substrate layer 302, and a third substrate layer 303. While three substrate layers are shown, it should be understood that more or less substrate layers may be included. The first substrate layer 301 forms a top or first side of substrate 300 and is vertically above the second substrate layer 302. The second substrate layer 302 forms a middle of substrate 300 and is vertically above the third substrate layer 303. The third substrate layer 303 forms a bottom or second side of substrate 300. Each substrate layer 301-303 may include an embedded glass fiber or cloth 304 (pre-preg) extending horizontally throughout the layer. The embedded glass fiber 304 may be vertically centered within the respective layer or may be offset as shown in the first substrate layer 301. The offset of the glass fiber 304 in the first substrate layer 301 allows for the formation of cavity 310 without damaging the glass fiber 304.

The semiconductor substrate 300 may include a cavity 310, a plurality of cavity interconnections 320 in the cavity 310, a third side region 330, a fourth side region 340, a semiconductor die 350, and a capacitor 360. The cavity 310 is horizontally centered in the first substrate layer 301 on a top or first side of substrate 300. While the cavity 310 is shown horizontally centered in the substrate 300, it should be understood that the cavity 310 may be offset from the center of the substrate 300. While the cavity 310 is shown extending from the top or first side of substrate 300 into the first substrate layer 301, is should be understood that the cavity 310 can extend beyond the first substrate layer including extending into the third substrate layer 303.

The plurality of cavity interconnections 320 may be embedded in a bottom surface of the cavity 310 such that each of the plurality of cavity interconnections 320 is recessed or below a horizontal plane of the bottom surface of the cavity 310. The plurality of cavity interconnections 320 may be vertically below the bottom surface of the cavity 310 at various depths but preferably between 1 and 4 microns deep. The plurality of cavity interconnections 320 may provide a conductive path within the substrate 300 between each of the plurality of cavity interconnections 320 as well as between the plurality of cavity interconnections 320 and both the third side region 330 and the fourth side region 340.

The third side region 330 is horizontally adjacent to the cavity 310 on a left side of the cavity 310 and the fourth side region 340 is horizontally adjacent to the cavity 310 on a right side of the cavity 310 opposite the third side region 330. The third side region 330 and the fourth side region 340 extend from the top or first side of substrate 300 to the bottom or second side of substrate 300. The third side region may include a plurality of third side interconnections 331 extending from the top or first side of the substrate 300 to the bottom or second side of the substrate 300. Each of the plurality of third side interconnections 331 may include an electrically conductive stop etch layer 332 located within the first substrate layer 301 in the same horizontal plane as the bottom of the cavity 310 (horizontally above a surface of the plurality of cavity interconnections 320). The plurality of third side interconnections 331 may provide a conductive path from the top or first side of the substrate 300 to the bottom or second side of the substrate 300 as well as to the plurality of cavity interconnections 320 and, thorough the plurality of cavity interconnections 320, to a plurality of fourth side interconnections 341.

The fourth side region 340 may include a plurality of fourth side interconnections 341 extending from the top or first side of the substrate 300 to the bottom or second side of the substrate 300. Each of the plurality of fourth side interconnections 311 may include an electrically conductive stop etch layer 342 located within the first substrate layer 301 in the same horizontal plane as the bottom of the cavity 310 (horizontally above a surface of the plurality of cavity interconnections 320). The plurality of fourth side interconnections 341 may provide a conductive path from the top or first side of the substrate 300 to the bottom or second side of the substrate 300 as well as to the plurality of cavity interconnections 320 and, thorough the plurality of cavity interconnections 320, to the plurality of third side interconnections 331.

The semiconductor die 350 is shown at the bottom or second side of the substrate 300 while the capacitor 360 is shown on the top or first side of substrate 300 but these positions may be switched. The semiconductor die 350 may be a number of different devices, such as a logic die or a memory die. The semiconductor die 350 may be centered at the bottom or second side of substrate 300 and include die connections 351 and underfill material 352. The die connections 351 couple the die 350 to the plurality of cavity interconnections 320. The substrate 300 may also include solder balls or connection points 305 that provide an external connection for the interconnections 331 and 341 to other devices or components not shown, such as a printed circuit board. The capacitor 360 may be a number of different devices, such as a logic die, memory die, or an inductor. The capacitor 360 may be centered within the cavity 310.

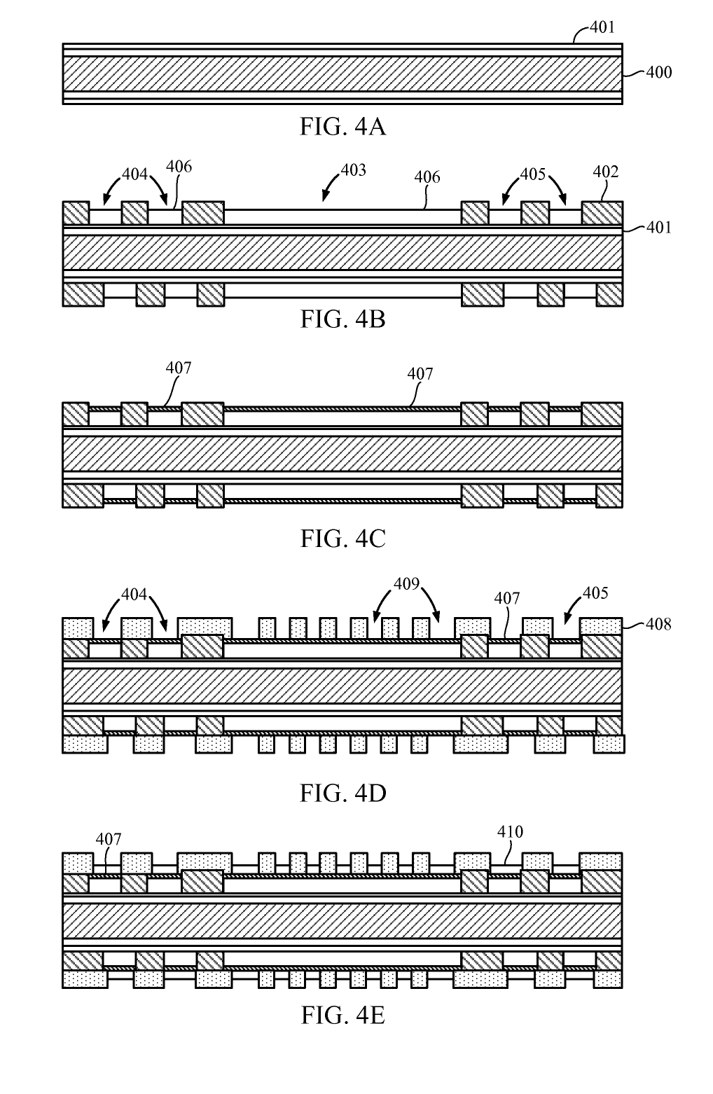

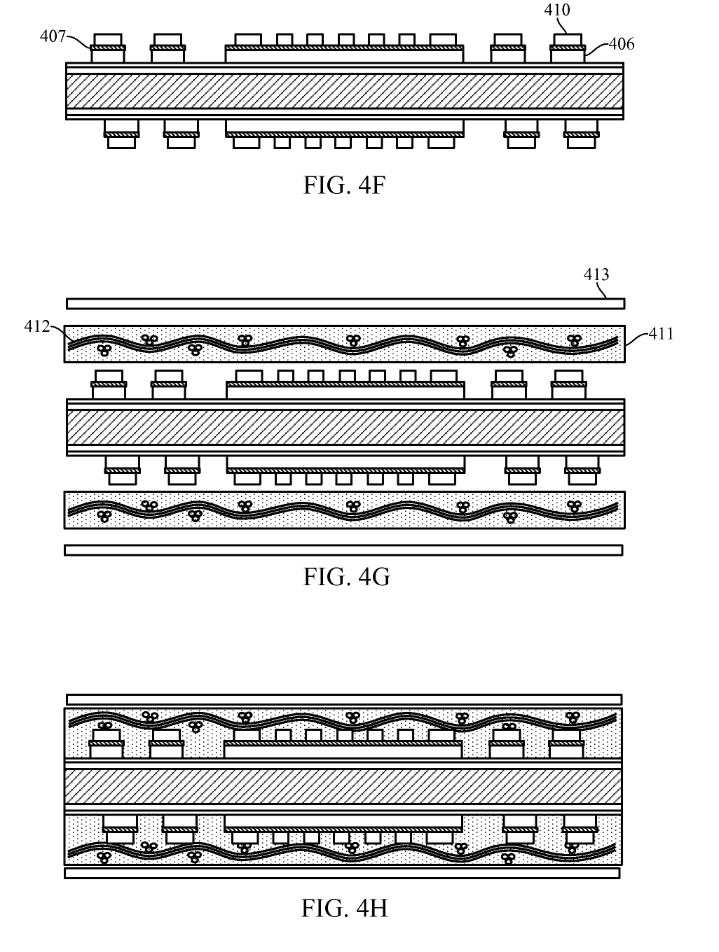

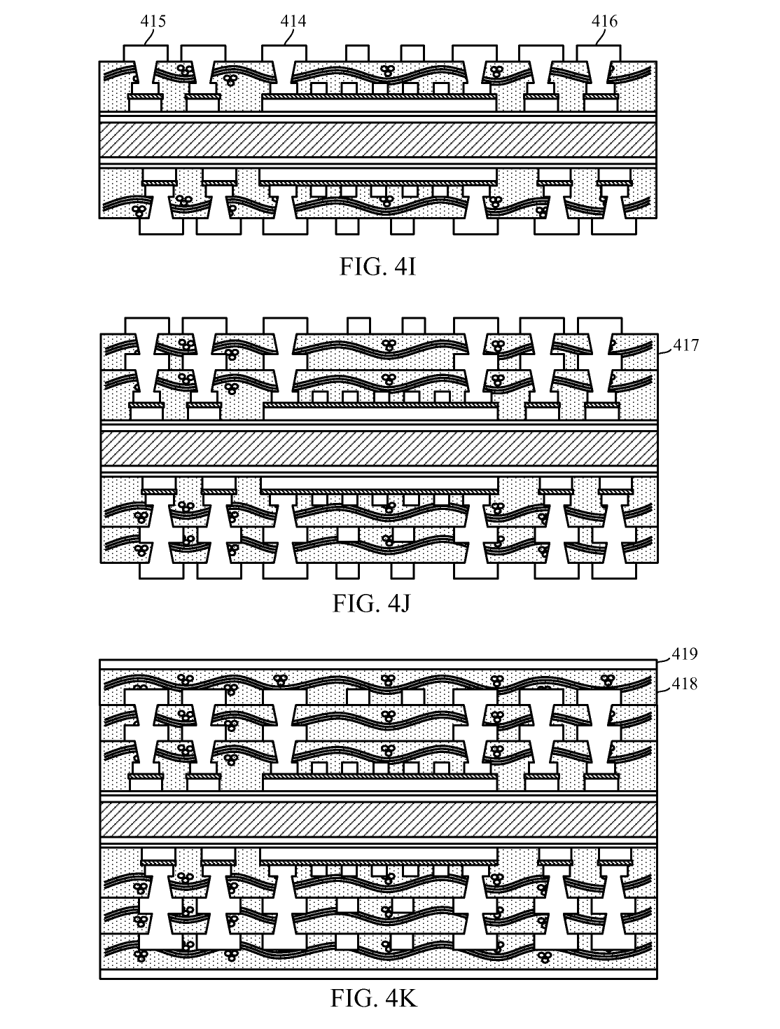

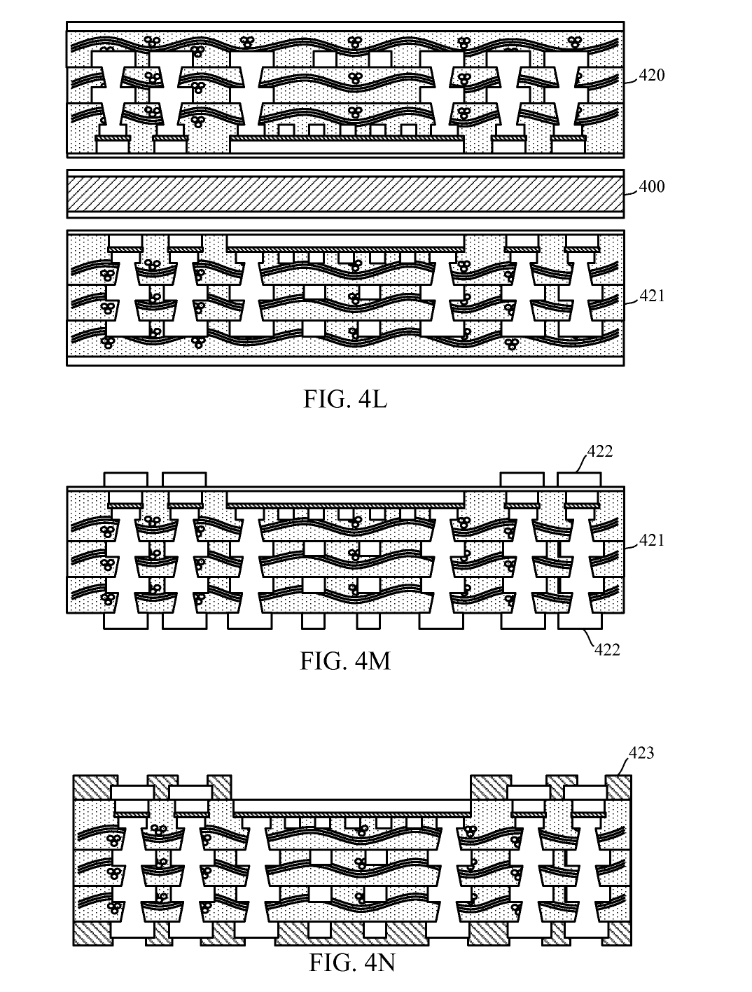

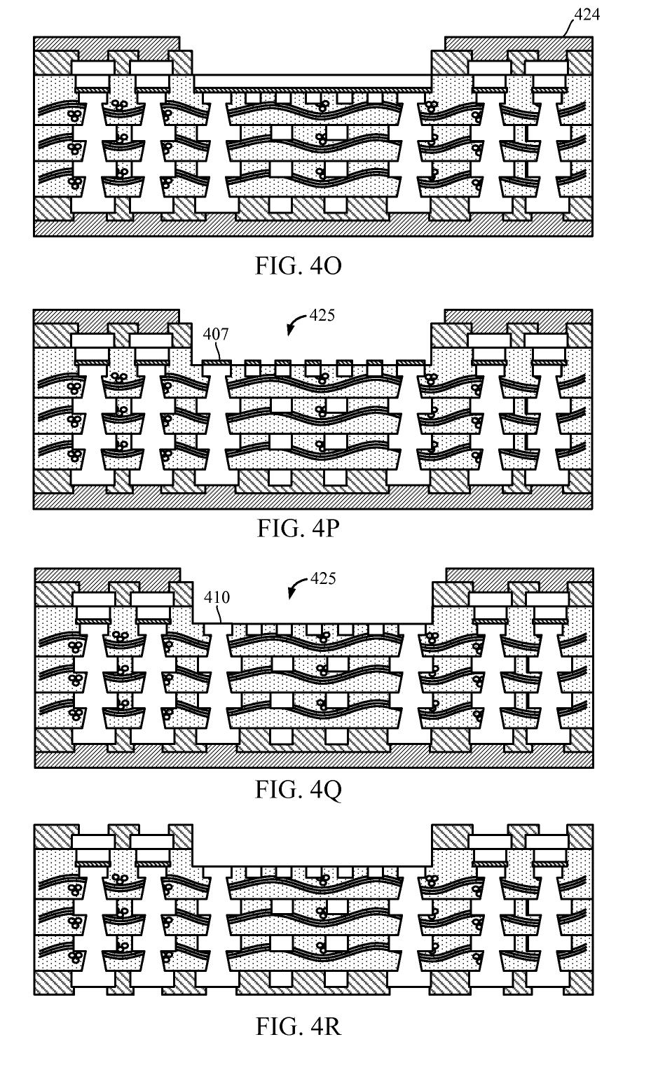

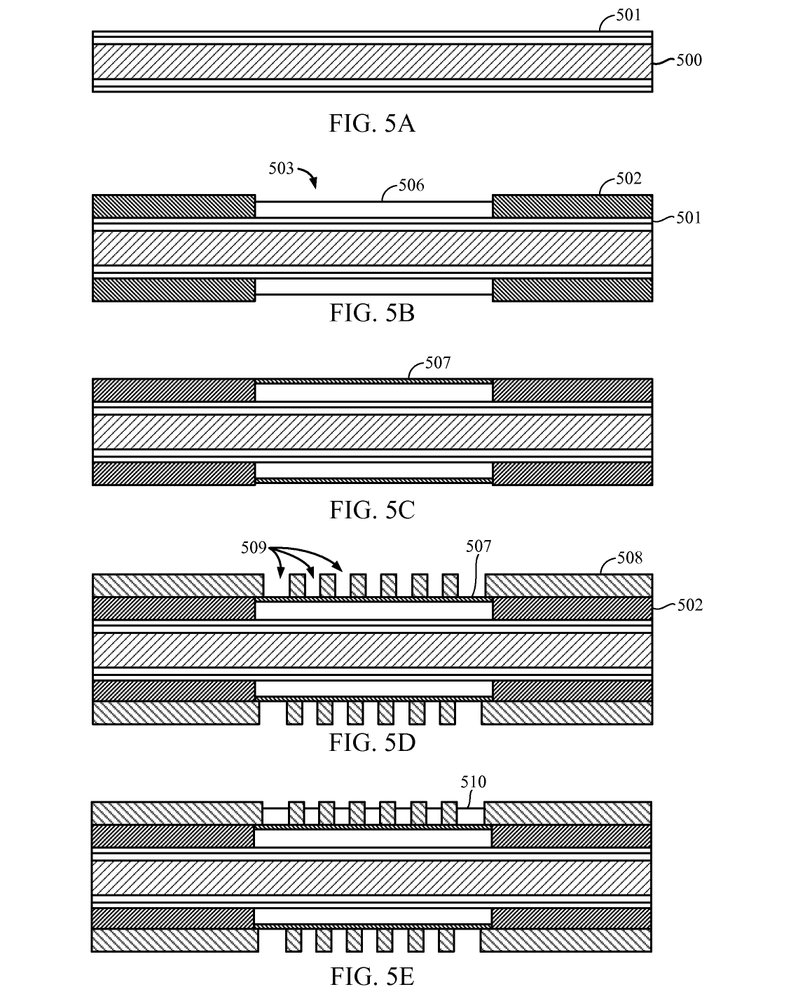

FIGS. 4A-R depict a partial process flow for forming a semiconductor package with a cavity having embedded interconnections in accordance with some examples of the disclosure. While the process flow depicts forming two semiconductor substrates (one above and one below a carrier), it should be understood that only one substrate may be formed instead and the following process flow will be described using only the substrate formed above the carrier. As shown in FIG. 4A, the partial process flow begins with a carrier 400 having a first seed layer 401. As shown in FIG. 4B, the process continues by applying a first removable layer 402 to the seed layer 401. The first removable layer 402 may then be patterned to form a cavity region 403, a plurality of first side interconnection regions 404 horizontally adjacent the cavity region 403, and a plurality of second side interconnection regions 405 horizontally adjacent the cavity region 403 opposite the plurality of first side interconnection regions 404. Next, a first electrically conductive material 406 is applied in the cavity region 403, the plurality of first side interconnection regions 404, and the plurality of second side interconnection regions 405. The electrically conductive material may be copper, for example.

As shown in FIG. 4C, an electrically conductive etch stop layer 407 is then applied to or on the first electrically conductive material 406. The electrically conductive etch stop layer 407 may be of various vertical thickness, but is preferably 1 to 4 microns thick. Next and as shown in FIG. 4D, a second removable layer 408 is applied to or on the first removable layer 402 and the electrically conductive etch stop layer 407. The second removable layer 408 may then be patterned to form a plurality of cavity interconnection regions 409 and continue to form the plurality of first side interconnection regions 404 and the plurality of second side interconnection regions 405 while exposing the electrically conductive etch stop layer 407. Next and as shown in FIG. 4E, a second electrically conductive material 410 is applied in the plurality of cavity interconnection regions 409, the plurality of first side interconnection regions 404, and the plurality of second side interconnection regions 405. The second electrically conductive material 410 is applied on the surface of the exposed electrically conductive etch stop layer 407. Next and as shown in FIG. 4F, the first removable layer 402 and the second removable layer 408 are removed.

Next and as shown in FIG. 4G, a first dielectric substrate layer 411 is applied on or to a surface of the second electrically conductive material 410. The first dielectric substrate layer 411 may have an embedded glass fiber 412 extending horizontally from side to side and vertically offset from center of the first dielectric substrate layer 411. This portion of the process flow results in the first electrically conductive material 406 and the second electrically conductive material 410 becoming embedded within the first dielectric substrate layer 411 as shown in FIG. 4H. Next, a second copper seed layer 413 is applied to or on a surface of first dielectric substrate layer 411 opposite the first seed layer 401.

Next and as shown in FIG. 4I, the second seed layer 413 may be patterned and etched to form a plurality of cavity interconnections 414, a plurality of first side interconnections 415, and a plurality of second side interconnections 416. The plurality of first side interconnections 415, the plurality of second side interconnections 416 and a first portion of the plurality of cavity interconnections 414 extend from a top or surface of the structure through the first dielectric substrate layer 411 to the first seed layer 401. A second portion of the plurality of cavity interconnections 414 extends vertically only partially into the first dielectric substrate layer 411 but extends horizontally through the first dielectric substrate layer 411 to create horizontal connections therein. Because of the first electrically conductive material 406, the electrically conductive stop etch layer 407, and the second electrically conductive material 410 are in contact and stacked on top of one another, a conductive path is formed by the plurality of first side interconnections 415, the plurality of second side interconnections 416, and the first portion of the plurality of cavity interconnections 414 from one side of the structure to an opposite side of the structure (once the carrier 400 is removed).

Next and as shown in FIG. 4J, a second dielectric substrate layer 417 is applied on or to a surface of the first dielectric layer 411 similar to the process flow shown in FIGS. 4G through 41. Next and as shown in FIG. 4K, a third dielectric substrate layer 418 is applied on or to the surface of the second dielectric layer 417. Next, a final seed layer 419 is applied to or on the surface of the third dielectric substrate layer 418. While three dielectric substrate layers are shown, it should be understood that more or less than three may be applied depending on the desired height of the structure along with other factors. Next and as shown in FIG. 4L, the carrier 400 is separate from the structure to form two semiconductor substrates 420 and 421.

The following portion of the description will focus on only the semiconductor substrate 421, but it should be understood that the additional process flow may be applied to both semiconductor substrates 420 and 421. Next and as shown in FIG. 4M, the first seed layer 401 and the final seed layer 419 are patterned and etched to form external contact points, bumps, or landing pads 422. Next and as shown in FIG. 4N, a three stage process is applied. In the three stage process: a SR coating 423 is applied, exposed, and then developed. Next and as shown in FIG. 4O, an etch mask 424 is applied to the first side interconnect region 404 and the second side interconnect region 405 on the top surface of substrate 421 and along the entire bottom surface of substrate 421. Next and as shown in FIG. 4P, the substrate 421 is etched to create a cavity. The etching step removes the first electrically conductive material 406 from the cavity region 403 until it reaches the electrically conductive etch stop layer 407 forming a cavity 425. Next and as shown in FIG. 4Q, the electrically conductive etch stop layer 407 is removed from a bottom surface of the cavity 425 to expose the second electrically conductive material 410, which is recessed or below the bottom surface of cavity 425. Next and as shown in FIG. 4R, the SR coating 423 is removed. Additional process steps may then take place as desired.

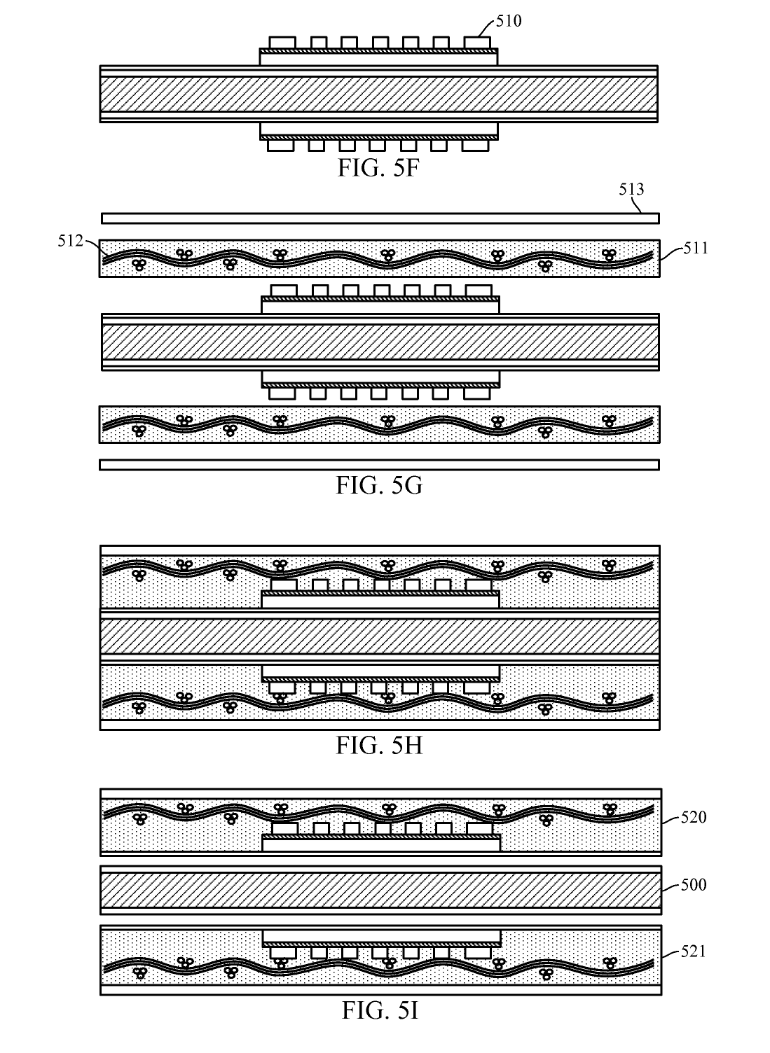

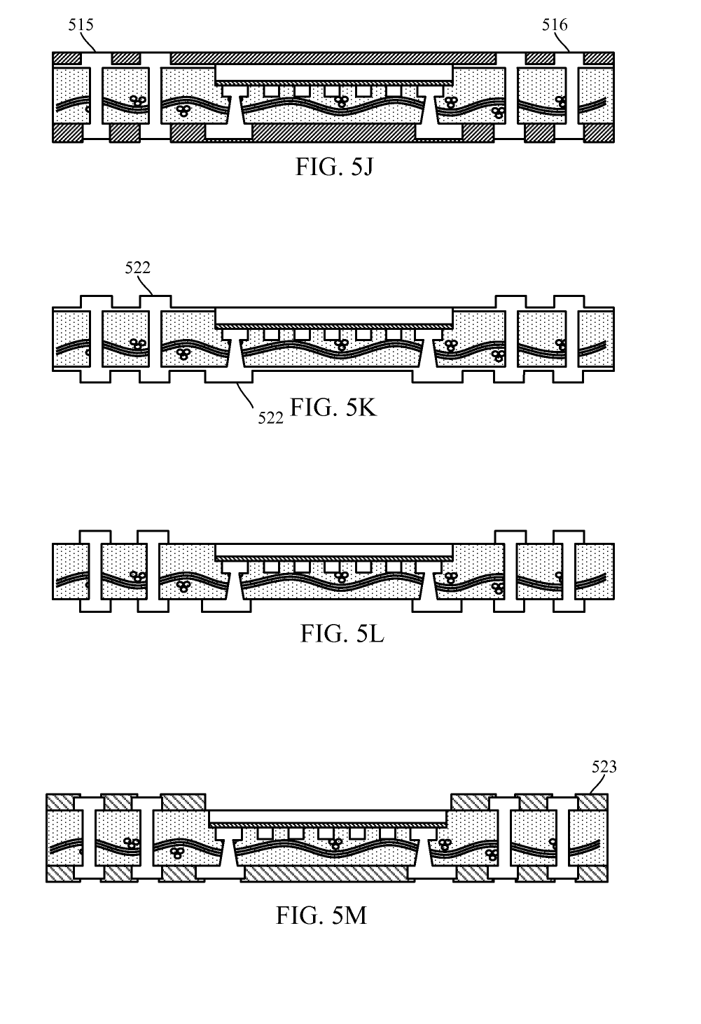

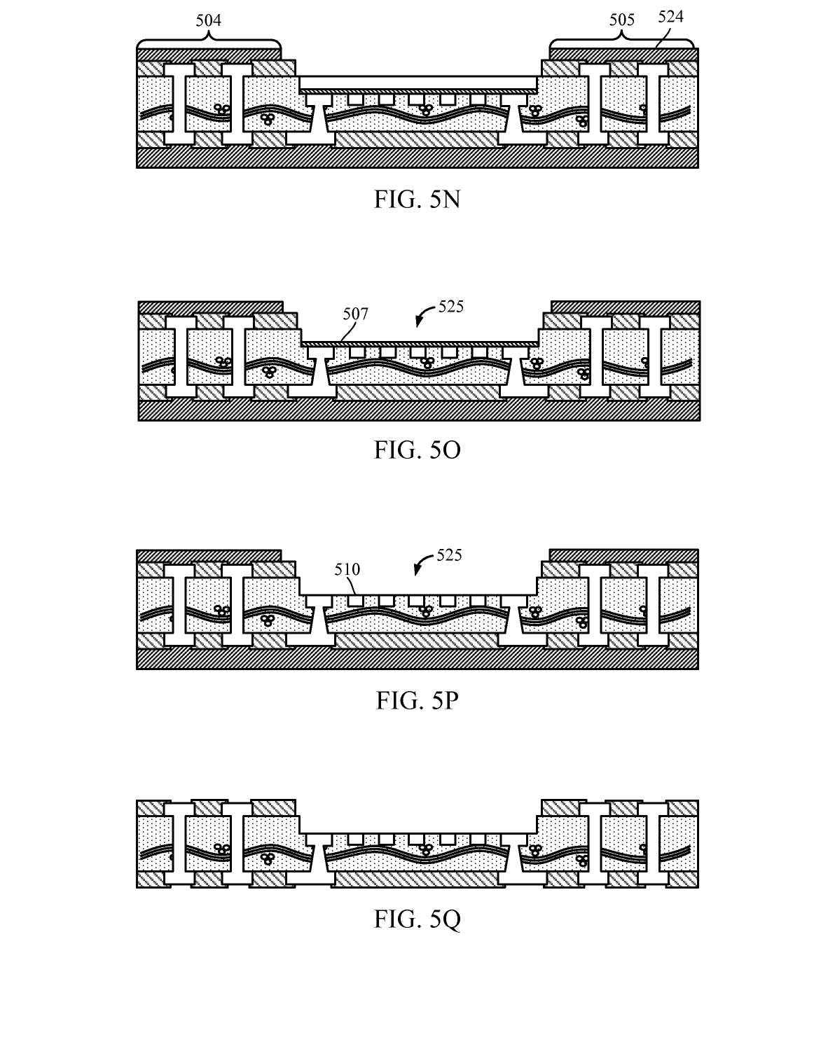

FIGS. 5A-Q depict a partial process flow for forming a semiconductor package with a cavity having embedded interconnections and separately formed side interconnections in accordance with some examples of the disclosure. While the process flow depicts forming two semiconductor substrates (one above and one below a carrier), it should be understood that only one substrate may be formed instead and the following process flow will be described using only the substrate formed above the carrier. As shown in FIG. 5A, the partial process flow begins with a carrier 500 having a first seed layer 501. As shown in FIG. 5B, the process continues by applying a first removable layer 502 to the seed layer 501. The first removable layer 502 may then be patterned to form a cavity region 503. Next, a first electrically conductive material 506 is applied in the cavity region 503. The first electrically conductive material 506 may be copper, for example.

As shown in FIG. 5C, an electrically conductive etch stop layer 507 is then applied to or on the first electrically conductive material 506. The electrically conductive etch stop layer 507 may be of varying vertical thickness, but is preferably 1 to 5 microns thick. Next and as shown in FIG. 5D, a second removable layer 508 is applied to or on the first removable layer 502 and the electrically conductive etch stop layer 507. The second removable layer 508 may then be patterned to form a plurality of cavity interconnection regions 509 while exposing the electrically conductive etch stop layer 507. Next and as shown in FIG. 5E, a second electrically conductive material 510 is applied in the plurality of cavity interconnection regions 509. The second electrically conductive material 510 is applied on the surface of the exposed electrically conductive etch stop layer 507. Next and as shown in FIG. 5F, the first removable layer 502 and the second removable layer 508 are removed.

Next and as shown in FIG. 5G, a first dielectric substrate layer 511 is applied on or to a surface of the second electrically conductive material 510. The first dielectric substrate layer 511 may have an embedded glass fiber 512 extending horizontally from side to side and vertically offset from center of the first dielectric substrate layer 511. This portion of the process flow results in the first electrically conductive material 506 and the second electrically conductive material 510 becoming embedded within the first dielectric substrate layer 511 as shown in FIG. 5H. Next, a second copper seed layer 513 is applied to or on a surface of first dielectric substrate layer 511 opposite the first seed layer 501.

Next and as shown in FIG. 5I, the carrier 500 is separate from the structure to form two semiconductor substrates 520 and 521. The following portion of the description will focus on only the semiconductor substrate 521, but it should be understood that the additional process flow may be applied to both semiconductor substrates 520 and 521. Next and as shown in FIG. 5J, a mask layer 519 is applied on a top surface and a bottom surface of the substrate 521 and patterned to form a plurality of cavity interconnections 514, a plurality of first side interconnections 515, and a plurality of second side interconnections 516. Then a drilling process extends the cavity interconnections 514 from the second electrically conductive material 510 to an external connection point, bump, or landing pad 522, and extends both the plurality of first side interconnections 515 and the plurality of second side interconnections 516 from the top of substrate 521 to the bottom of substrate 521. Next and as shown in FIG. 5K, the mask layer 519 is removed. Next and as shown in FIG. 5L, the first seed layer 501 is etched and removed.

Next and as shown in FIG. 5M, a three stage process is applied. In the three stage process: a SR coating 523 is applied, exposed, and then developed. Next and as shown in FIG. 5N, an etch mask 524 is applied to a first side interconnect region 504 and the second side interconnect region 505 on the top surface of substrate 521 and along the entire bottom surface of substrate 521. Next and as shown in FIG. 5O, the substrate 521 is etched to create a cavity. The etching step removes the first electrically conductive material 506 from the cavity region 503 until it reaches the electrically conductive etch stop layer 507 forming a cavity 525. Next and as shown in FIG. 5P, the electrically conductive etch stop layer 507 is removed from a bottom surface of the cavity 525 to expose the second electrically conductive material 510, which is recessed or below the bottom surface of cavity 525. Next and as shown in FIG. 5Q, the etch mask 524 is removed. Additional process steps may then take place as desired.

Nothing stated or illustrated depicted in this application is intended to dedicate any component, step, feature, benefit, advantage, or equivalent to the public, regardless of whether the component, step, feature, benefit, advantage, or the equivalent is recited in the claims.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the examples disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it goes without saying that these aspects also constitute a description of the corresponding method, and so a block or a component of a device should also be understood as a corresponding method step or as a feature of a method step. Analogously thereto, aspects described in connection with or as a method step also constitute a description of a corresponding block or detail or feature of a corresponding device. Some or all of the method steps can be performed by a hardware apparatus (or using a hardware apparatus), such as, for example, a microprocessor, a programmable computer or an electronic circuit. In some examples, some or a plurality of the most important method steps can be performed by such an apparatus.

The examples described above merely constitute an illustration of the principles of the present disclosure. It goes without saying that modifications and variations of the arrangements and details described herein will become apparent to other persons skilled in the art. Therefore, it is intended that the disclosure be restricted only by the scope of protection of the appended patent claims, rather than by the specific details presented on the basis of the description and the explanation of the examples herein.

In the detailed description above it can be seen that different features are grouped together in examples. This manner of disclosure should not be understood as an intention that the claimed examples require more features than are explicitly mentioned in the respective claim. Rather, the situation is such that inventive content may reside in fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods disclosed in the description or in the claims can be implemented by a device comprising means for performing the respective steps or actions of this method.

Furthermore, in some examples, an individual step/action can be subdivided into a plurality of sub-steps or contain a plurality of sub-steps. Such sub-steps can be contained in the disclosure of the individual step and be part of the disclosure of the individual step.

While the foregoing disclosure shows illustrative examples of the disclosure, it should be noted that various changes and modifications could be made herein without departing from the scope of the disclosure as defined by the appended claims. The functions, steps and/or actions of the method claims in accordance with the examples of the disclosure described herein need not be performed in any particular order. Furthermore, although elements of the disclosure may be described or claimed in the singular, the plural is contemplated unless limitation to the singular is explicitly stated.

1. A semiconductor substrate, comprising:
a substrate having a top side, a bottom side opposite the top side, a cavity in the top side of the substrate, a first side portion horizontally adjacent the cavity, and a second side portion horizontally adjacent the cavity opposite from the first side portion;
a plurality of cavity interconnections located in a bottom surface of the cavity, the plurality of cavity interconnections providing a conductive path between the cavity and the bottom side;
a plurality of first side interconnections located in the first side portion and extending from the top side of the substrate to the bottom side of the substrate; and
a plurality of second side interconnections located in the second side portion and extending from the top side of the substrate to the bottom side of the substrate.

2. The semiconductor substrate of claim 1, wherein the plurality of cavity interconnections are located vertically below the bottom surface of the cavity.

3. The semiconductor substrate of claim 2, wherein a surface of each of the plurality of cavity interconnections is approximately 1 to 4 microns vertically below the bottom surface of the cavity.

4. The semiconductor substrate of claim 3, further comprising an electrically conductive etch stop layer in each of the plurality of the first side interconnections and in each of the plurality of second side interconnections.

5. The semiconductor substrate of claim 4, wherein the electrically conductive etch stop layer is in a same plane as the bottom surface of the cavity.

6. The semiconductor substrate of claim 5, wherein the plurality of cavity interconnections provide a first conductive path between the plurality of first side interconnections and the plurality of cavity interconnections.

7. The semiconductor substrate of claim 6, wherein the plurality of cavity interconnections provide a second conductive path between the plurality of second side interconnections and the plurality of cavity interconnections.

8. The semiconductor substrate of claim 7, wherein the plurality of cavity interconnections provide a third conductive path between the plurality of first side interconnections and the plurality of second side interconnection.

9. The semiconductor substrate of claim 8, wherein the substrate comprises a first dielectric layer having a glass fiber extending horizontally from a first side edge to a second side edge opposite the first side edge.

10. The semiconductor substrate of claim 9, wherein the glass fiber is vertically offset from a center of the first dielectric layer.

11. The semiconductor substrate of claim 10, wherein the substrate comprises a second dielectric layer having a glass fiber extending horizontally from a first side edge to a second side edge opposite the first side edge and a third dielectric layer have a glass fiber extending horizontally from a first side edge to a second side edge opposite the first side edge.

12. The semiconductor substrate of claim 11, further comprising a semiconductor die located in the cavity and coupled to the plurality of cavity interconnections.

13. The semiconductor substrate of claim 12, further comprising a capacitor located on the bottom surface of the substrate.

14. The semiconductor substrate of claim 11, further comprising a capacitor located in the cavity.

15. The semiconductor substrate of claim 11, wherein the semiconductor substrate is incorporated into one of a mobile phone, a mobile communication device, a pager, a personal digital assistant, a personal information manager, a mobile hand-held computer, a laptop computer, a wireless device, or a wireless modem.

16. A semiconductor substrate, comprising:
a substrate having a top side, a bottom side opposite the top side, a cavity in the top side of the substrate, a first side portion horizontally adjacent the cavity, and a second side portion horizontally adjacent the cavity opposite from the first side portion; and
a plurality of cavity interconnections located vertically below a bottom surface of the cavity, the plurality of cavity interconnections providing a conductive path between the cavity and the bottom side.

17. The semiconductor substrate of claim 16, further comprising:
a plurality of first side interconnections located in the first side portion and extending from the top side of the substrate to the bottom side of the substrate; and
a plurality of second side interconnections located in the second side portion and extending from the top side of the substrate to the bottom side of the substrate.

18. The semiconductor substrate of claim 17, wherein a surface of each of the plurality of cavity interconnections is approximately 1 to 4 microns vertically below the bottom surface of the cavity.

19. The semiconductor substrate of claim 18, further comprising an electrically conductive etch stop layer in each of the plurality of the first side interconnections and in each of the plurality of second side interconnections.

20. The semiconductor substrate of claim 19, wherein the electrically conductive etch stop layer is in a same plane as the bottom surface of the cavity.

21. The semiconductor substrate of claim 20, wherein the plurality of cavity interconnections provide a first conductive path between the plurality of first side interconnections and the plurality of cavity interconnections.

22. The semiconductor substrate of claim 21, wherein the plurality of cavity interconnections provide a second conductive path between the plurality of second side interconnections and the plurality of cavity interconnections.

23. The semiconductor substrate of claim 22, wherein the plurality of cavity interconnections provide a third conductive path between the plurality of first side interconnections and the plurality of second side interconnection.

24. The semiconductor substrate of claim 23, wherein the substrate comprises a first dielectric layer having a glass fiber extending horizontally from a first side edge to a second side edge opposite the first side edge.

25. The semiconductor substrate of claim 24, wherein the glass fiber is vertically offset from a center of the first dielectric layer.

26. The semiconductor substrate of claim 25, wherein the substrate comprises a second dielectric layer having a glass fiber extending horizontally from a first side edge to a second side edge opposite the first side edge and a third dielectric layer have a glass fiber extending horizontally from a first side edge to a second side edge opposite the first side edge.

27. The semiconductor substrate of claim 26, wherein the semiconductor substrate is incorporated into one of a mobile phone, a mobile communication device, a pager, a personal digital assistant, a personal information manager, a mobile hand-held computer, a laptop computer, a wireless device, or a wireless modem.

28. A method of forming a semiconductor substrate having side interconnections and a cavity with embedded interconnections, the method comprising:
applying a seed layer to a carrier;
applying a first removable layer on a surface of the seed layer;
patterning the first removable layer to create a cavity region, a plurality of first side interconnect regions horizontally adjacent to the cavity region, and a plurality of second side interconnect regions horizontally adjacent to the cavity region on an opposite side from the plurality of second side interconnect regions;
applying an first electrically conductive material in the cavity region, the plurality of first side interconnect regions, and the plurality of second side interconnect regions;
applying an electrically conductive etch stop layer on the first electrically conductive material;
applying a second removable layer on the electrically conductive etch stop layer and the patterned first removable layer;
patterning the second removable layer to form a plurality of cavity interconnect regions and to continue to form the plurality of first side interconnect regions and the plurality of second side interconnect regions;
applying a second electrically conductive material in the plurality of cavity interconnect regions, the plurality of first side interconnect regions, and the plurality of second side interconnect regions;
removing the first removable layer and the second removable layer;
applying a dielectric layer on a surface of the second electrically conductive material;
removing the seed layer and the carrier to expose the cavity region; and
removing the first electrically conductive material from the cavity region.

29. The method of claim 28, wherein the electrically conductive etch stop layer is approximately 1 to 4 microns in thickness.

30. The method of claim 29, wherein patterning the second removable layer exposes the electrically conductive etch stop layer.
